(19) United States
(12) Patent Application Publication
(10) Pub. No.: US 2020/0185495 A1
(43) Pub. Date: Jun. 11, 2020

(54) SEMICONDUCTOR DEVICES AND METHODS FOR FORMING SAME

(71) Applicant: Winbond Electronics Corp., Taichung City (TW)

(72) Inventors: Chien-Hsu TSENG, Taichung City (TW); Chia-Lan HSU, Taichung City (TW); Kai JEN, Taichung City (TW); Yi-Hao CHIEN, Taichung City (TW)

(21) Appl. No.: 16/216,089

(22) Filed: Dec. 11, 2018

(51) Int. Cl. H01L 29/06; H01L 21/768; H01L 21/764

(52) U.S. Cl. CPC H01L 29/0649; H01L 21/764; H01L 21/76832

(57) ABSTRACT

A semiconductor device is provided, including a substrate; a dielectric structure over the substrate; and a capping layer over the dielectric structure. The bottom of the capping layer has an M-shaped cross section. The capping layer and the dielectric structure are formed of different materials.

### BACKGROUND

### Technical Field

The present disclosure relates to semiconductor manufacturing, and in particular it relates to semiconductor devices and methods for forming same.

### Description of the Related Art

As semiconductor devices are gradually miniaturized, the difficulty of fabricating these semiconductor devices increases dramatically. Defects may be formed in the semiconductor devices during the manufacturing process, and this may cause the performance of the semiconductor devices to suffer, or it may damage the semiconductor devices. Therefore, semiconductor devices must be continuously improved to increase the yield and improve the process window.

### BRIEF SUMMARY

In accordance with some embodiments of the present disclosure, a semiconductor device is provided. The semiconductor device includes a substrate; a dielectric structure over the substrate; and a cap layer over the dielectric structure, wherein a bottom of the cap layer has an M-shaped cross section, and the cap layer and the dielectric structure are formed of different materials.

In accordance with some embodiments of the present disclosure, a method of forming semiconductor devices is provided. The method includes providing a substrate; forming a dielectric structure over the substrate; forming a first cap layer having a U-shaped cross section over the dielectric structure; and forming a second cap layer over the first cap layer, wherein the second cap layer has a pair of foot portions on opposite sides of the first cap layer extending toward the substrate such that bottoms of the first cap layer and the second cap layer form an M-shaped cross section.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIGS. 1A-1E are cross-sectional views of a semiconductor device at various stages of manufacture, accordance to some embodiments of the present disclosure.

FIGS. 2A-2E are cross-sectional views of a semiconductor device at various stages of manufacture, according to another embodiments of the present disclosure.

FIGS. 3-4 are cross-sectional views of semiconductor devices, according to still other embodiments of the present disclosure.

### DETAILED DESCRIPTION

The following outlines several embodiments so that those skilled in the art may better understand the present disclosure. However, these embodiments are not intended to limit the present disclosure. It is understandable that those skilled in the art may adjust the embodiments described below according to requirements, for example, changing the order of processes and/or including more or fewer steps than described herein.

Furthermore, other elements may be added on the basis of the embodiments described below. For example, the description of “forming a second element on a first element” may include embodiments in which the first element is in direct contact with the second element, and may also include embodiments in which additional elements are disposed between the first element and the second element such that the first element and the second element are not in direct contact, and the spatially relative descriptors of the first element and the second element may change as the device is operated or used in different orientations.

The present disclosure utilizes a cap layer having an M-shaped bottom cross section to protect an underlying layer from being exposed by subsequent processes such as an etch process. Thus, unwanted leakage and short-circuit paths can be avoided, thereby improving the yield of semiconductor devices. In the following embodiments, the manufacture of memory devices will be described as an example. However, the cap layer of the present disclosure may also be applicable to the manufacture of other semiconductor devices, for example, analog/logic circuits, optoelectronic semiconductors, microelectromechanical systems (MEMS), or the like.

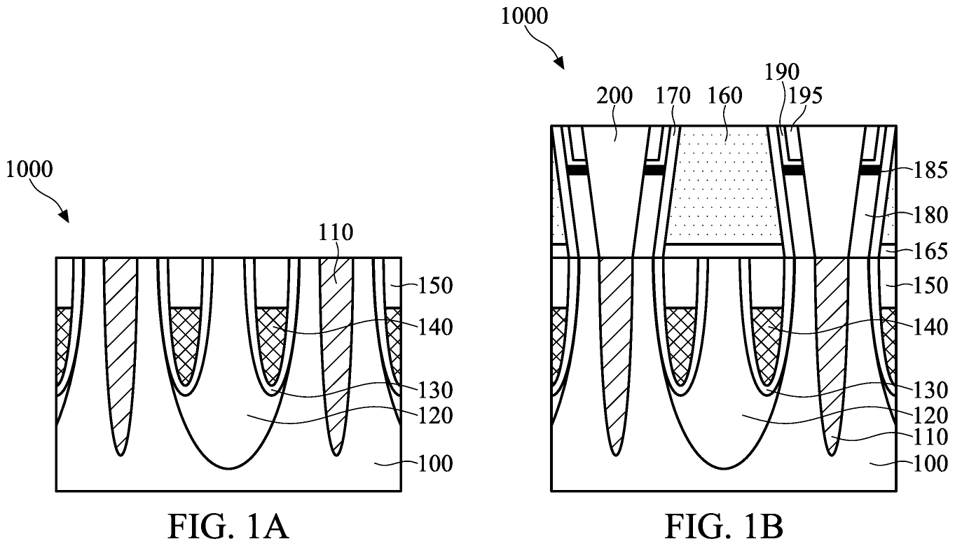

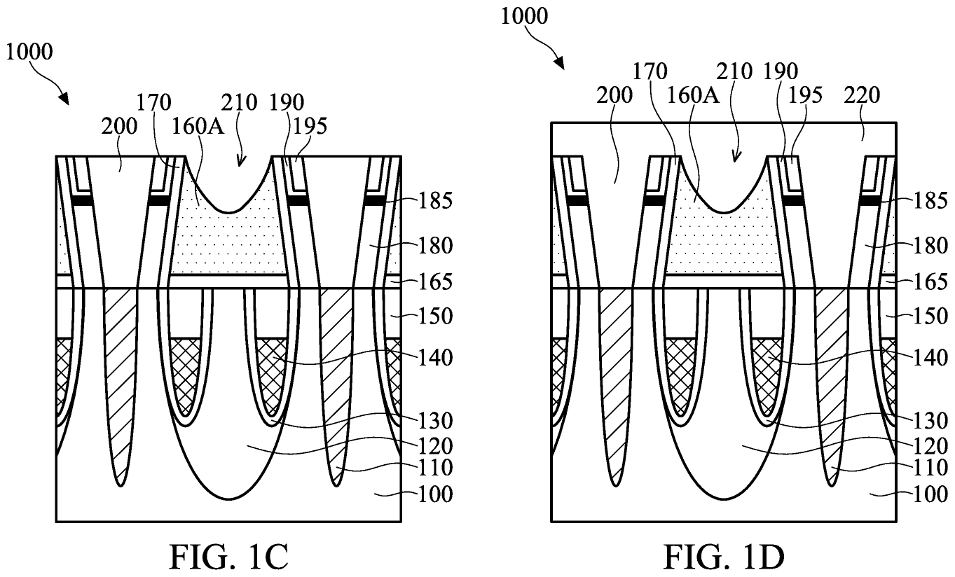

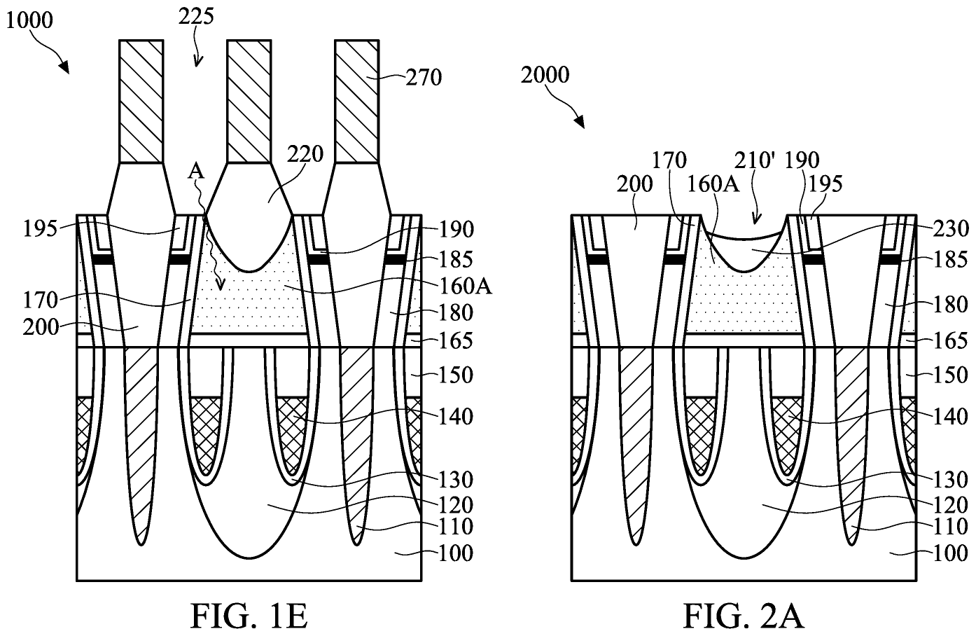

FIGS. 1A-1H are cross-sectional views illustrating a semiconductor device 1000 at various stages of manufacture, according to some embodiments of the present disclosure. As shown in FIG. 1A, the substrate 100 is first provided. Any substrate material applicable for a semiconductor device may be used, and may be a bulk semiconductor substrate or a composite substrate formed of different materials. In addition, different semiconductor elements may be formed on the substrate 100 in advance.

In some embodiments, an isolation structure 110 and an isolation structure 120 are formed in the substrate 100, wherein the isolation structure 110 and the isolation structure 120 extend in the same direction, and the isolation structure 110 is in the substrate 100 which is adjacent to the isolation structure 120, as shown in FIG. 1A. In some embodiments, the isolation structure 110 and the isolation structure 120 may each independently include a single layer, a double layer, or a multilayer structure.

In some embodiments, forming the isolation structure 110 and the isolation structure 120 includes forming trenches by an etch process, and then filling the trenches with insulating materials of the isolation structure 110 and the isolation structure 120 by a deposition process. The deposition process may include a chemical vapor deposition (CVD) process or a plasma-enhanced chemical vapor deposition (PECVD) process. The insulating materials of the isolation structure 110 and the isolation structure 120 may include silicon oxide, silicon nitride, silicon oxynitride, a combination thereof, or the like. Moreover, isolation structure 110 and isolation structure 120 may be made of the same or different materials.

Then, a barrier layer 130, a word line 140, and an insulating structure 150 are formed in the isolation structure 120 by an etch process and a deposition process. The barrier layer 130 may include silicon oxide, silicon nitride, silicon oxynitride, a combination thereof, or the like. The word line 140 may include a conductive material, for example, amorphous silicon (a-Si), polysilicon (poly-Si), metal, metal silicide, metal nitride, conductive metal oxide, a combination thereof, or the like. The insulating structure 150 may include silicon oxide, silicon nitride, silicon oxynitride, a combination thereof, or the like.

As shown in FIG. 1B, an etch stop layer 165 and a dielectric layer 160 are sequentially formed over the substrate 100. The dielectric layer 160 is an interlayer dielectric (ILD) layer and may include phosphosilicate glass (PSG), borosilicate glass (BSG), fluorinated silicate glass (FSG), boron-doped phosphosilicate glass (BPSG), undoped silicate glass (USG), tetraethyl orthosilicate (TEOS) oxide, a low-k material, silicon oxide, silicon nitride, silicon oxynitride, spin-on glass, a combination thereof, or the like. The etch stop layer 165 may include silicon nitride, silicon oxynitride, a combination thereof, or the like. In an embodiment, forming the dielectric layer 160 and etch stop layer 165 may include a deposition process, for example, chemical vapor deposition, spin coating, or the like.

Then, an opening through the dielectric layer 160 and the etch stop layer 165 is formed by, for example, a patterning process to expose the substrate 100, and a protective layer 170, a first conductive structure 180, a silicide region 185, a liner layer 190, and a second conductive structure 195 are formed in the opening, wherein the protective layer 170 covers opposite sides of the dielectric layer 160 and the etch stop layer 165 to protect the dielectric layer 160 from being damaged during the formation process of the first conductive structure 180, the silicide region 185, the liner layer 190, and the second conductive structure 195. The protective layer 170 may include silicon nitride, silicon oxynitride, a combination thereof, or the like, and may be formed by using, for example, a chemical vapor deposition (CVD) process.

Then, the first conductive structure 180 may be formed by a deposition process and an etch back process. The first conductive structure 180 may include a semiconductor material, such as a doped or undoped polysilicon. In an embodiment, the first conductive structure 180 may include metallic material, for example, copper, aluminum, tungsten, a combination thereof, or the like. The silicide region 185, the liner layer 190, and the second conductive structure 195 are then sequentially formed on the first conductive structure 180, wherein the formation of the silicide region 185 is selective. In an embodiment where the first conductive structure 180 includes polysilicon, the first conductive structure 180 has a silicide region 185 thereon. The liner layer 190 may be made of titanium nitride, tantalum nitride, tungsten nitride, a combination thereof, or the like. The second conductive structure 195 may include a metallic material, for example, tungsten (W), copper (Cu), aluminum (Al), gold (Au), chromium (Cr), nickel (Ni), platinum (Pt), titanium (Ti), a combination thereof, or the like.

Then, an opening is formed by etching through the first conductive structure 180, the silicide region 185, the liner layer 190, and the second conductive structure 195 to expose the isolation structure 110 in the substrate 100. An insulating material is deposited in the opening to form the insulating structure 200.

Then, the dielectric layer 160 may be recessed by an etch process to form a cap layer over the dielectric structure 160 for protecting the dielectric structure 160. As shown in FIG. 1C, the etch process etches a recess in a middle portion of the dielectric structure 160 to form a dielectric structure 160A which have a recess 210 on a top portion. The etch process may include a dry etch process such as reactive-ion etching (RIE), electron cyclotron resonance (ECR) etching, inductively coupled plasma (ICP) etching, neutral beam etching (NBE), and the like. Furthermore, the shape of the recess 210 is not limited to the U shape as illustrated, and may be a V shape or another shape.

Then, a first cap layer material 220 may overfill the recess 210 during a deposition process, as shown in FIG. 1D. The deposition process may include atomic layer deposition (ALD), chemical vapor deposition (CVD), a combination thereof, or the like. The first cap layer material 220 may be made of a material having a different etch selectivity than the dielectric structure 160A. In an embodiment, the first cap layer material 220 may include silicon oxide, silicon nitride, silicon oxynitride, silicon carbide, silicon carbonitride, a combination thereof, or the like.

Then, a capacitor is formed on this structure. As shown in FIG. 1E, a dielectric layer 270 is formed over the first cap layer material 220, and then the dielectric layer 270 is etched to form trenches 225 exposing the second conductive structure 195 to form capacitors therein.

However, at this stage, the adjacent dielectric structure 160A may be exposed due to situations such as process variation, resulting in an unwanted leakage and short-circuit paths (as indicated by arrow A), causing damage to the semiconductor device 1000. Accordingly, the present disclosure further provides the following embodiments to solve the above problems.

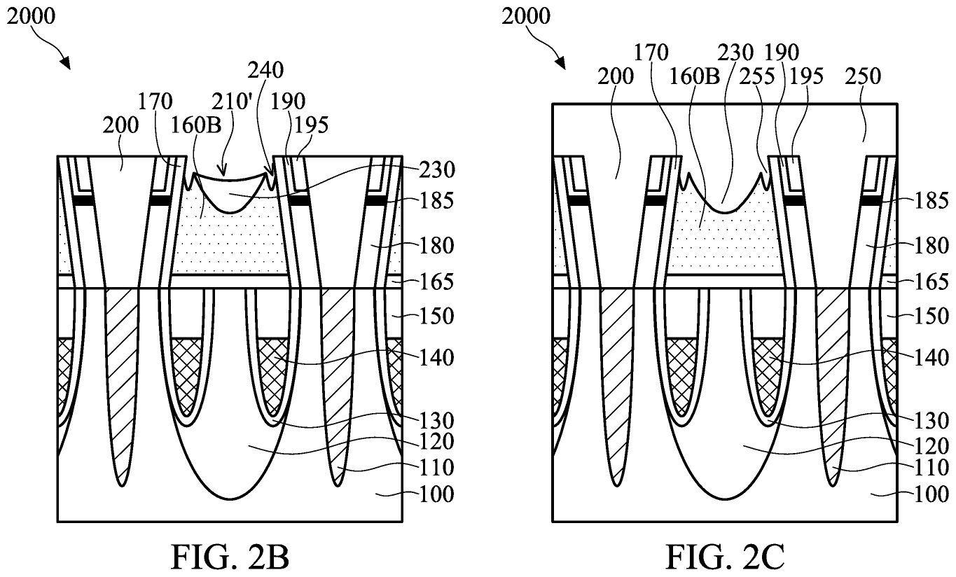

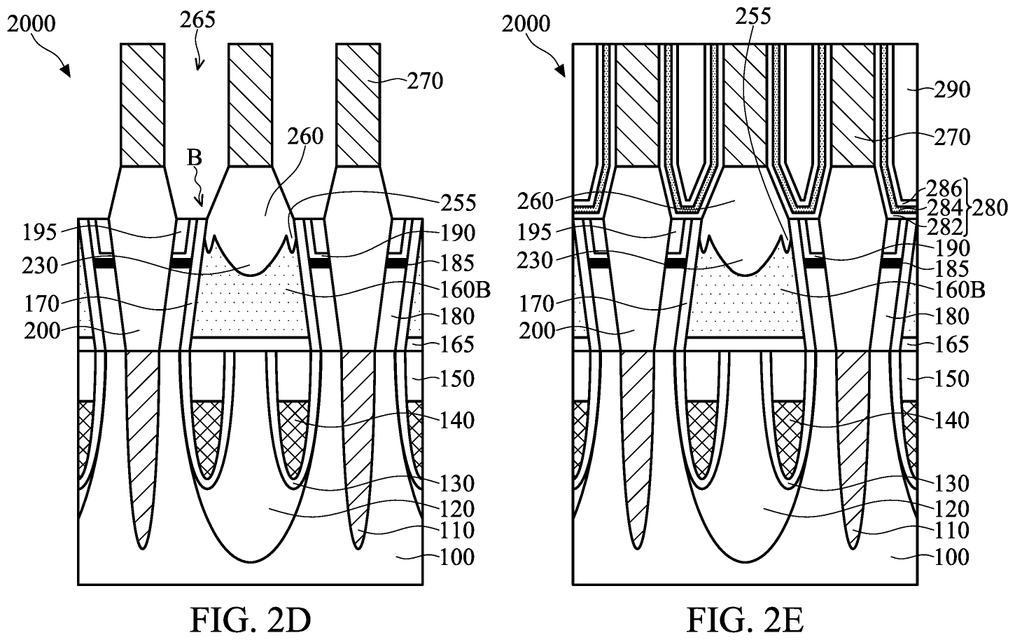

FIGS. 2A-2E are cross-sectional views illustrating a semiconductor device 2000 at various stages of manufacture, according to some embodiments of the present disclosure. FIG. 2A is subsequent to the process step in FIG. 1D, and for the sake of simplicity, the same or similar reference numbers are used to depict same or similar elements. The formation and materials of these elements are as described above and will not be repeated again. Compared to the embodiment of FIGS. 1A-1E, the following embodiments will further adjust the shape of the cap layer to prevent the dielectric structure 160A from being exposed by subsequent etch processes.

As shown in FIG. 2A, the first cap layer material 220 may be etched back until a plurality of peripheral portions of the dielectric structure 160A are exposed, and a first cap layer 230 and a recess 210′ over the first cap layer 230 are formed. In an embodiment, the etch back of the first cap layer material 220 may be a dry etch process, for example, reactive-ion etching (RIE), electron cyclotron resonance (ECR) etching, inductively coupled plasma (ICP) etching, neutral beam etching (NBE), a combination thereof, or the like.

In addition, the shape of a upper surface of the first cap layer 230 is not limited to the concave surface as illustrated, and may be a convex surface, a substantially horizontal plane, or another shape, and the shape of the bottom of the first cap layer 230 is not limited to the U-shaped cross section, and may be a V-shape or another shape.

Then, gaps 240 may be formed on opposite sides of the first cap layer 230 by an etch process with the first cap layer 230 as a mask for etching the peripheral portions of the dielectric structure 160A exposed by the first cap layer 230, as shown in FIG. 2B. In some embodiments, bottoms of the gaps 240 are not lower than the bottom of the first cap layer 230. The etched dielectric structure 160A forms a dielectric structure 160B. The dielectric structure 160B has a reduced top height compared to dielectric structure 160A. In an embodiment, the etch process may include a dry etch process and/or a wet etch process having different etch rates for the first cap layer 230 and the dielectric structure 160A.

Then, as shown in FIG. 2C, during the deposition process, a second cap layer material 250 overfills the gaps 240 and the recess 210′ over the first cap layer 230 for separating a top portion of the dielectric structure 160B from the top portion of the protective layer 170 to protect the dielectric structure 160B from defects caused by subsequent processing, thereby improving the yield of the semiconductor device 2000.

As shown in FIG. 2C, a second cap layer material 250 deposited in these gaps 240 forms a pair of foot portions 255 that extend toward the substrate 100, the bottoms of the pair of foot portions 255 form an M-shaped bottom cross section with the bottom of the first cap layer 230. In addition, since the etch process removes a portion of the dielectric structure 160A over the first cap layer 230, an edge of the second cap layer material 250 of the pair of foot portions 255 and an edge of the dielectric structure 160B form a common sidewall on the protective layer 170.

In an embodiment, a deposition process of the second cap layer material 250 may include atomic layer deposition (ALD), chemical vapor deposition (CVD), a combination thereof, or the like. In an embodiment, the second cap layer material 250 may include silicon oxide, silicon nitride, silicon oxynitride, silicon carbide, silicon carbonitride, a combination thereof, or the like. In a particular embodiment, the second cap layer material 250 may be the same material as the first cap layer 230, for example, silicon nitride. In other embodiments, the second cap layer material 250 may be made of a different material than the first cover layer 230. It should be understood that, although the interface between the first cap layer 230 and the second cap layer material 250 is not illustrated in the drawings, when the second cap layer material 250 is made of different materials than the first cap layer 230, there is an interface between the first cap layer 230 and the second cap layer material 250.

The, a dielectric layer 270 is formed over the second cap layer material 250, and then the dielectric layer 270 is etched to form trenches 265 which expose the second conductive structure 195 to form capacitors therein, as shown in FIG. 2D. Since the top portion of the dielectric structure 160B is protected by the cap layer at this stage, the cap layer includes a composite cap layer of the first cap layer 230 and the second cap layer 260, so that the top portion of the dielectric structure 160B is not exposed. Thus, unwanted leakage and short-circuit paths (as indicated by arrow B) can be avoided, thereby increasing the yield of the semiconductor device 2000.

In some embodiments, the dielectric structure 270 may be made of a doped or undoped dielectric material, such as phosphosilicate glass (PSG), borosilicate glass (BSG), fluorinated silicate glass (FSG), boron-doped phosphosilicate glass (BPSG), undoped silicate glass (USG), tetraethyl orthosilicate (TEOS) oxide, a low-k material, silicon oxide, silicon nitride, silicon oxynitride, spin-on glass, a combination thereof, or the like. The dielectric structure 270 may be formed in a deposition process. In addition, the shape of the top portion of the second cover layer 260 is not limited to substantially being a flat upper surface as illustrated in the drawing, and may be convex, concave, or another topography. The shape of sidewalls of the second cover layer 260 is not limited to the sloping sidewalls illustrated in the drawing, and may also substantially be vertical sidewalls or another topography.

Then, a lower electrode layer 282, a dielectric layer 284, and an upper electrode layer 286 of a capacitor 280 are sequentially formed, and then the remaining space of the trenches 265 is filled to form a dielectric layer 290 covering the capacitor 280, as shown in FIG. 2E. The lower electrode layer 282 and the upper electrode layer 286 may be formed of a metal material such as titanium, tantalum, titanium nitride, or tantalum nitride. The dielectric layer 284 may be formed of a high-k dielectric material such as zirconia oxide, alumina oxide, a combination thereof, or the like. The dielectric layer 290 may be made of silicon oxide, silicon nitride, silicon oxynitride, a combination thereof, or the like. The dielectric layer 290 may be formed in a deposition process.

As described above, the present disclosure provides a composite cap layer including the first cap layer 230 and the second cap layer 260 in the semiconductor device 2000. The bottom of the first cap layer 230 and the bottom of the second cap layer 260 form the M-shaped cross section to protect the top portion of the dielectric structure 160B from being exposed during subsequent etch processes and causing leakage or the formation of short-circuit paths, thereby improving the yield of the semiconductor device 2000.

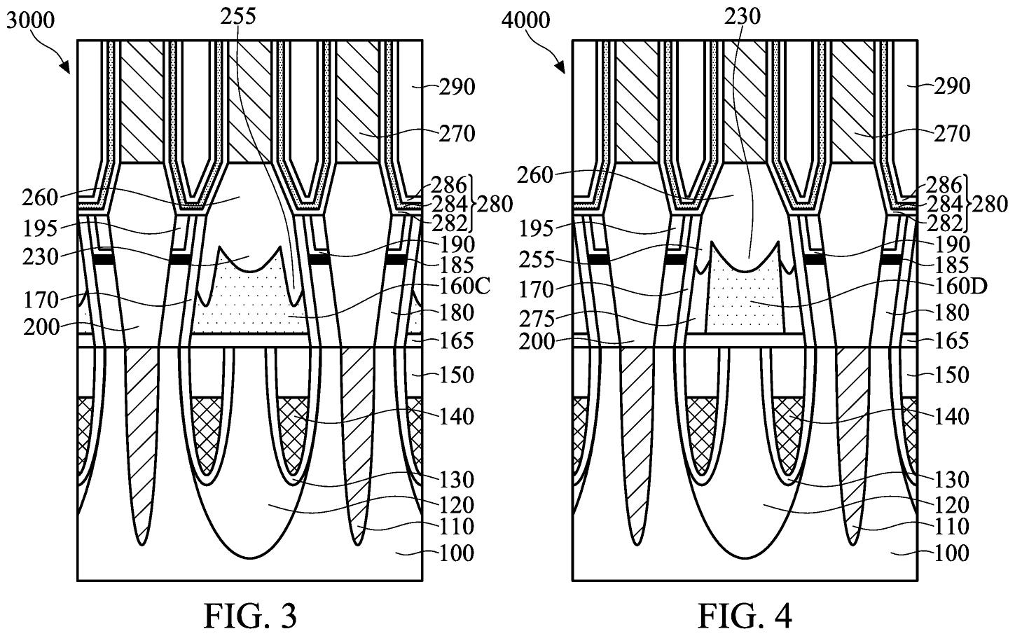

It is to be noted that although a bottom of a middle portion of the M-shaped cross section of the cap layer in FIGS. 2A-2E is lower than the bottom of the opposite sides (foot 255), the present disclosure is not limited thereto. The gaps 240 may further extend downward during the formation of the gaps 240 by etching the plurality of peripheral portions of the dielectric structure 160A in FIG. 2B, such that the bottom of each of the opposite sides (foot portions 255) is lower than the bottom of the middle portion to ensure that the subsequently formed cap layer may cover the dielectric structure 160C (as shown in FIG. 3), so that the dielectric structure 160C is not exposed in subsequent etch processes to generate leakage and short-circuit paths, and the yield of the semiconductor device 3000 is improved.

FIG. 4 is cross-sectional view of a semiconductor device 4000, according to still other embodiments of the present disclosure. Similarly, fabrication steps of the embodiment shown in FIG. 4 are substantially the same as those in FIGS. 2A-2E, except that during the process of forming the gaps 240 by etching the plurality of peripheral portions of the dielectric structure 160A in FIG. 2B, the dielectric structure 160A is etched until the bottom of each of the gaps 240 extends through the dielectric structure 160A and the gaps 240 expose the etch stop layer 165 under the dielectric structure 160A. The resulting dielectric structure after the etch process described above is represented by symbol 160D. Next, during the process of depositing the second cap layer material 250 in the gaps 240 as illustrated in FIG. 2C to form the pair of foot portions 255 extending toward the substrate 100, the pair of foot portions 255 may be formed only in the upper half portion of the gaps 240 to form air gaps 275. In the present embodiment, since the semiconductor device 4000 has the air gaps 275, the parasitic capacitance of bit line to bit line can be reduced further.

As described above, the present disclosure forms a cap layer having an M-shaped cross section in a semiconductor device by two etch processes and two deposition processes, thereby preventing the dielectric structure from being exposed in a subsequent etch process and avoiding leakage and the formation of short-circuit paths which can damage the semiconductor device. Therefore, the present disclosure provides a composite cap layer that includes a first cap layer and a second cap layer in the semiconductor device to improve the yield of the semiconductor devices. In addition, a cap layer with an M-shaped bottom cross section can completely cover the dielectric structure, thus improving the process window.

Although the present disclosure has been described above by various embodiments, these embodiments are not intended to limit the disclosure. Those skilled in the art should appreciate that they may make various changes, substitutions and alterations on the basis of the embodiments of the present disclosure to realize the same purposes and/or advantages as the various embodiments described herein. Those skilled in the art should also appreciate that the present disclosure may be practiced without departing from the spirit and scope of the disclosure. Therefore, the scope of protection of the present disclosure is defined as the subject matter set forth in the appended claims

What is claimed is:

1. A semiconductor device, comprising:
a substrate;
a dielectric structure over the substrate; and
a cap layer over the dielectric structure, wherein a bottom of the cap layer has an M-shaped cross section, and the cap layer and the dielectric structure are formed of different materials.

2. The semiconductor device as claimed in claim 1, wherein the cap layer is a composite cap layer comprising:
a first cap layer having a U-shaped cross section; and
a second cap layer on the first cap layer and having a pair of foot portions on opposite sides of the first cap layer.

3. The semiconductor device as claimed in claim 2, wherein the first cap layer comprises a material having a different etch selectivity than the dielectric structure.

4. The semiconductor device as claimed in claim 2, further comprising a pair of air gaps between the pair of foot portions and the substrate.

5. The semiconductor device as claimed in claim 1, wherein an edge of the cap layer and an edge of the dielectric structure form a common sidewall.

6. The semiconductor device as claimed in claim 1, further comprising a pair of conductive structures over the substrate, wherein the dielectric structure is between the pair of conductive structures.

7. The semiconductor device as claimed in claim 1, further comprising a capacitor, wherein a bottom of a capacitor adjoins the cap layer.

8. A method of forming semiconductor devices, comprising:
providing a substrate;
forming a dielectric structure over the substrate;
forming a first cap layer having a U-shaped cross section over the dielectric structure; and
forming a second cap layer over the first cap layer, wherein the second cap layer has a pair of foot portions on opposite sides of the first cap layer extending toward the substrate such that bottoms of the first cap layer and the second cap layer form an M-shaped cross section.

9. The method as claimed in claim 8, wherein forming the first cap layer comprises:
etching the dielectric structure to form a U-shaped recess on a middle portion of the dielectric structure;
overfilling a first cap layer material in the U-shaped recess; and
etching back the first cap layer material until a plurality of peripheral portions of the dielectric structure are exposed.

10. The method as claimed in claim 9, wherein forming the second cap layer comprises:
etching the plurality of peripheral portions of the exposed dielectric structure with the first cap layer as a mask to form a plurality of gaps on opposite sides of the first cap layer; and
overfilling a second cap layer material in the plurality of gaps to form the pair of foot portions of the second cap layer.

11. The method as claimed in claim 10, wherein the second cap layer material fills a plurality of upper portions of the plurality of gaps to form a plurality of air gaps in a remaining portion of the plurality of gaps.

12. The method as claimed in claim 8, further comprising forming a pair of conductive structures over the substrate, wherein the dielectric structure is between the pair of conductive structures.

13. The semiconductor structure as claimed in claim 12, further comprising forming a capacitor over the pair of conductive structures and adjoining the second cap layer.
